(19) United States
(12) Patent Application Publication
(10) Pub. No.: US 2011/0128089 A1
(43) Pub. Date: Jun. 2, 2011

(54) SIGNAL TRANSMISSION DEVICE

(76) Inventors: Kohei Teramoto, Tokyo (JP); Tsuyoshi Nakada, Tokyo (JP); Hirofumi Sada, Tokyo (JP); Toshiyuki Okusa, Tokyo (JP); Junji Okada, Osaka (JP); Hayato Imamura, Tokyo (JP)

(21) Appl. No.: 13/056,127

(22) PCT Filed: Sep. 29, 2009
(86) PCT No.: PCT/JP2009/004985

§ 371 Date: Jan. 27, 2011

(30) Foreign Application Priority Data
Nov. 28, 2008 (JP) 2008-304989

(51) Int. Cl. H03H 7/38

(52) U.S. Cl. 333/33

(57) ABSTRACT

A signal transmission device 10 is constructed in such a way that transmitting equipment 11 and receiving equipment 12 are connected to each other via a transmission path which consists of at least hot and cold signal lines, and a signal output stage of the transmitting equipment 11 is comprised of a current output circuit 112 and a load impedance Z (113) for converting a current I₀ created by the current output circuit 112 into a voltage, the load impedance Z (113) has an end connected to the hot signal line (H) of the transmission path 13 and another end connected to the cold signal line (C) of the transmission path, and the cold signal line (C) of the transmission path is connected to a ground terminal (GND_{B}) of the receiving equipment 12.

### FIELD OF THE INVENTION

The present invention relates to a signal transmission device in which transmitting equipment and receiving equipment are connected to each other via a transmission path which consists of at least hot and cold signal lines.

### BACKGROUND OF THE INVENTION

A conventional signal transmission device 30 disclosed by patent reference 1 which uses an unbalanced transmission method to transmit a signal is constructed in such a way that transmitting equipment 31 and receiving equipment 32 are connected to each other via a signal line 33 and a power source line 34, for example, as illustrated in FIG. 3 showing the circuit structure of the conventional signal transmission device.

For example, in a case in which the signal transmission device 30 is applied to audio equipment, the transmitting equipment 31 is a CD (Compact Disc) player or preamplifier, and the receiving equipment 32 is a DAC (Digital Analog Converter) or main amplifier.

In the signal transmission device 30 shown in FIG. 3, while each of power transformers 311 and 321 blocks connection between the primary and secondary voltages of a not-shown power supply, because stray capacities (stray capacities C_{A} and C_{B}) exist between the primary windings and the secondary windings of the power transformers 311 and 321 respectively, an impedance is formed in each of the power transformers.

Therefore, a loop is formed of the signal line 33 and the power source line 34 from the viewpoint of high frequencies. Therefore, an input end voltage V_{B} at the receiving equipment 32 is equal to (V_{B}=V_{A}+V_{N}) which is the sum of an input voltage V_{A} and a noise voltage V_{N}, which is piggybacked onto the input voltage, occurring between the grounds (GND_{A} and GND_{B}) of the transmitting equipment 31 and the receiving equipment 32. This results in causing degradation in the SN ratio (Signal To Noise Rate), and increase in the sound distortion.

Furthermore, in the loop formed of the signal line 33 and the power source line 34, many contact points exist among the pieces of equipment and the terminals of connecting cables and so on. In a case in which different kinds of metals are used among these contact points, a small amount of diode component exists and provides a nonlinear characteristic for the current flowing through the loop, and therefore a part of a high frequency noise signal is detected and is converted into a noise in the audible band.

In FIG. 3, reference numeral 312 denotes a driver IC, reference numeral 322 denotes a receiver IC, and each of them is constructed of an operational amplifier. Furthermore, reference numeral 323 denotes an unbalanced voltage input circuit having a high input impedance.

In order to solve the above-mentioned problem, there has been proposed a conventional signal transmission circuit 40 in which, as shown in FIG. 4, transmitting equipment 41 is defined as a current output (I₀) from a current output circuit 412 and a current voltage conversion circuit 422 is disposed in receiving equipment 42, the signal transmission circuit 40 using a current transmission method of converting the output current received by the receiving equipment 42 into a voltage by using a resistor R0 to remove a noise resulting from a stray capacity (for example, refer to patent reference 2).

### RELATED ART DOCUMENT

### Patent Reference

Patent reference 1: JP, 8-186850, A
Patent reference 2: JP, 59-202740, A

### SUMMARY OF THE INVENTION

According to the technology disclosed by above-mentioned patent reference 2, as shown in FIG. 4, for example, because the voltage V_{B} occurring at the input stage of the receiving equipment 42 becomes equal to V_{B}=I₀×R₀ even if a noise voltage V_{N} occurs between the grounds of the transmitting equipment 41 and the receiving equipment 42, the noise voltage V_{N} is not transmitted to the receiving equipment 42 and therefore the influence of the noise can be avoided even if the noise voltage V_{N} occurs. However, according to the technology disclosed by patent reference 2, it is necessary to incorporate a current voltage conversion circuit 421 for exclusive use into the input stage of the receiving equipment 42. However, because the general-purpose unbalance voltage input circuit having a high input impedance cannot support such a current voltage conversion circuit, the general versatility is inhibited remarkably.

The present invention is made in order to solve the above-mentioned problem, and it is therefore an object of the present invention to provide a signal transmission device that can avoid the influence of a noise voltage occurring between the grounds of transmitting equipment and receiving equipment thereof without inhibiting the general versatility thereof.

In order to solve the above-mentioned problem, in accordance with the present invention, there is provided a signal transmission device in which transmitting equipment and receiving equipment are connected to each other via a transmission path which consists of at least hot and cold signal lines, in which a signal output stage of the transmitting equipment is comprised of a current output circuit and a load resistance or load impedance for converting a current created by the above-mentioned current output circuit into a voltage, the above-mentioned load resistance or load impedance has an end connected to the hot signal line of the above-mentioned transmission path and another end connected to the cold signal line of the above-mentioned transmission path, and the cold signal line of the above-mentioned transmission path is connected to a ground terminal of the above-mentioned receiving equipment.

In accordance with the present invention, there is provided an advantage of being able to avoid the influence of a noise voltage occurring between the grounds of the transmitting equipment and the receiving equipment without inhibiting the general versatility of the signal transmission device, and transmit only a transmission signal to the receiving equipment correctly

### BRIEF DESCRIPTION OF THE FIGURES

FIG. 1 is a view showing the circuit structure of a signal transmission device in accordance with Embodiment 1 of the present invention;

FIG. 2 is a view showing the circuit structure of a signal transmission device in accordance with Embodiment 2 of the present invention;

FIG. 3 is a view showing an example of the circuit structure of a conventional signal transmission device; and

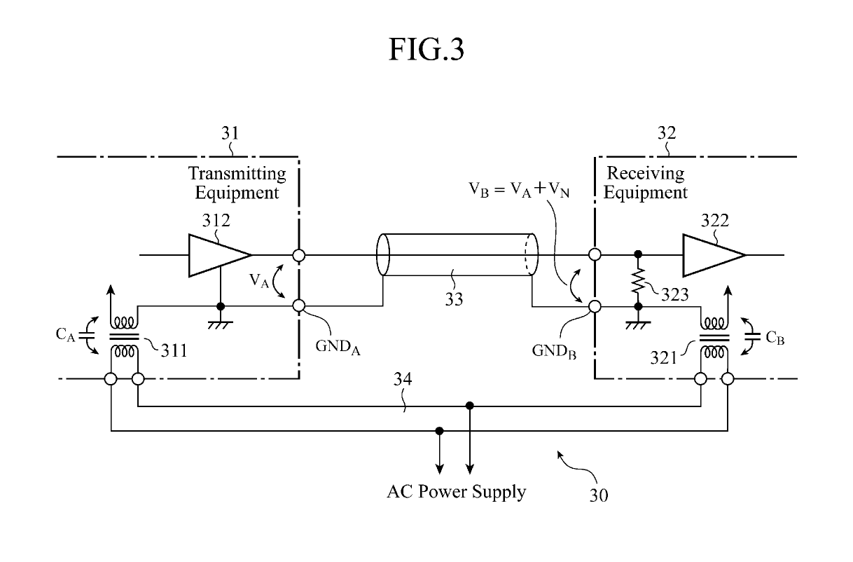

FIG. 4 is a view showing another example of the circuit structure of the conventional signal transmission device.

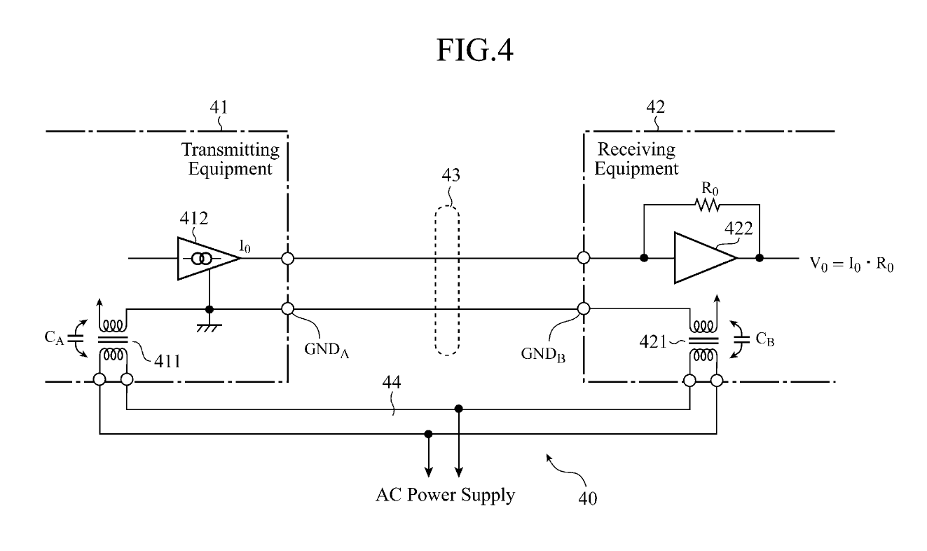

### EMBODIMENTS OF THE INVENTION

Hereafter, in order to explain this invention in greater detail, the preferred embodiments of the present invention will be described with reference to the accompanying drawings. Embodiment 1.

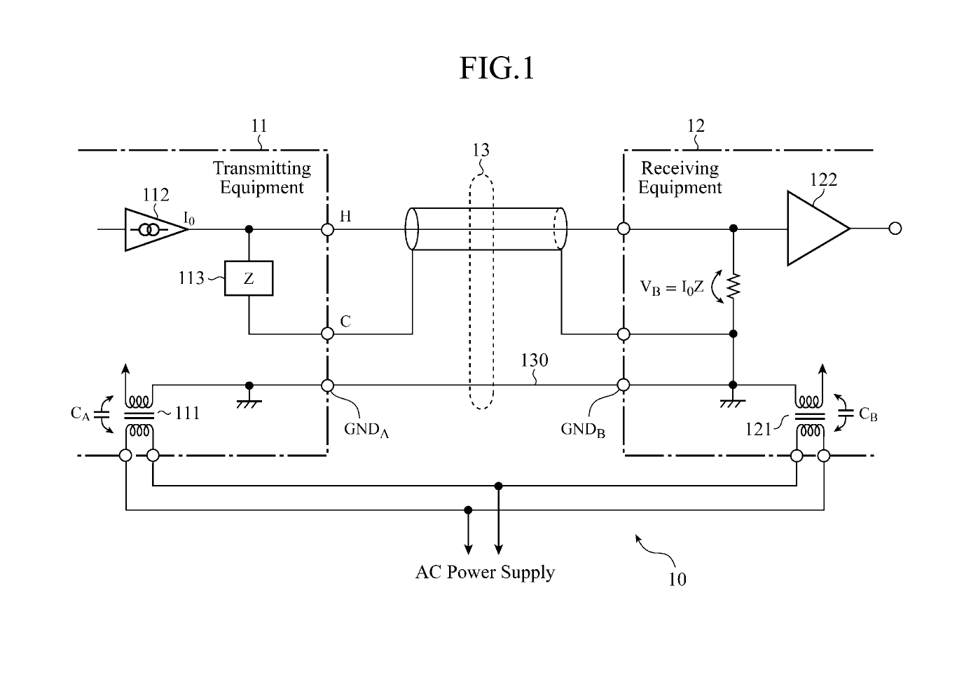

As shown in FIG. 1, a signal transmission device 10 in accordance with Embodiment 1 of the present invention is constructed in such a way that transmitting equipment 11 and receiving equipment 12 are connected to each other via a transmission path 13 which consists of at least a two-wire cable having a hot signal line (H) and a cold signal line (C).

The transmission path 13 includes a ground (GND) signal line 130 which connects between a ground terminal (GND_{A}) of the transmitting equipment 11 and a ground terminal (GND_{B}) of the receiving equipment 12, in addition to the above-mentioned two-wire signal line having the hot signal line (H) and the cold signal line (C).

In FIG. 1, a signal output stage of the transmitting equipment 11 is comprised of a current output circuit 112 and a load resistance or load impedance Z (referred to as a load impedance Z (113) from here on) for converting a current I₀ created by the current output circuit 112 into a voltage.

Furthermore, the load impedance Z (113) has an end connected to the hot signal line (H) of the transmission path 13 and another end connected to the cold signal line (C) of the transmission path 13, and the cold signal line (C) of the transmission path 13 is connected to the ground terminal (GND_{B}) of the receiving equipment 12.

In FIG. 1, reference numerals 111 and 121 denote power transformers, and reference numeral 122 denotes a receiver IC of the receiving equipment 12.

In the signal transmission device 10 in accordance with Embodiment 1 of the present invention having the above-mentioned structure, even if a difference occurs between the ground potential of the transmitting equipment 11 and that of the receiving equipment 12 (GND_{A} and GND_{B}) and hence a noise voltage V_{N} occurs, the output voltage signal V_{B} which the signal transmission device creates by carrying out current-to-voltage conversion of the output current I₀ of the current output circuit 112 of the transmitting equipment 11 by using the load impedance Z (113) is created with reference to the ground (GND_{B}) of the receiving equipment 12.

Therefore, because the voltage V_{B} occurring in the receiving equipment 12 becomes equal to V_{B}=I₀×Z even if the noise voltage V_{N} occurs between the grounds of the transmitting equipment 11 and the receiving equipment 12 (GND_{A} and GND_{B}), the noise voltage V_{N} is not transmitted to the receiving equipment 12 even if the noise voltage V_{N} occurs. Therefore, the influence of the noise voltage can be avoided. Furthermore, because the load impedance Z (113) is incorporated into the signal output stage of the transmitting equipment 11, the signal input stage of the receiving equipment 12 can be supported by the general-purpose unbalanced voltage input circuit having a high input impedance.

The above-mentioned signal transmission device 10 in accordance with Embodiment 1 of the present invention is constructed in such a way that the signal output stage of the transmitting equipment 11 is comprised of the current output circuit 112 and the load impedance Z (113) for converting the current I₀ created by the current output circuit 112 into a voltage, the end of the load impedance Z (113) is connected to the hot signal line (H) of the transmission path 13 and the other end of the load impedance is connected to the cold signal line (C) of the transmission path, and the cold signal line (C) of the transmission path is connected to the ground terminal (GND_{B}) of the receiving equipment 12. Therefore, the signal transmission device can avoid the influence of a noise voltage V_{N} occurring between the grounds (GND_{A}-GND_{B}) of the transmitting equipment 11 and the receiving equipment 12 without inhibiting the general versatility of the signal transmission device.

More specifically, because the signal transmission device 10 in accordance with Embodiment 1 of the present invention carries out current-to-voltage conversion of the output current I₀ of the current output circuit 112 of the transmitting equipment 11 by using the load impedance Z (113) to create the voltage signal V_{B} to be transmitted to the receiving equipment 12 with reference to the ground (GND_{B}) of the receiving equipment 12, the signal transmission device can transmit the voltage signal (V_{B}=I₀×Z) to the receiving equipment 12 without being affected by the influence of the noise voltage V_{N} occurring between the grounds (GND_{A}-GND_{B}) of the transmitting equipment 11 and the receiving equipment 12.

Therefore, for example, in a case in which the signal transmission device 10 in accordance with Embodiment 1 of the present invention is applied to audio equipment, the audio equipment can provide high sound quality. Particularly, in a case in which the signal transmission device in accordance with Embodiment 1 of the present invention is used for vehicle-mounted audio equipment which needs a measure against noise because of restrictions on its mounting space, significant advantages can be provided.

Furthermore, in the signal transmission device 10 in accordance with Embodiment 1 of the present invention, the single GND signal line 130 is added to the transmission path 13 in order to connect between the grounds (GND_{A}-GND_{B}) of the transmitting equipment 11 and the receiving equipment 12, though because the load impedance Z (113) is incorporated into the signal output stage of the transmitting equipment 11, any special consideration does not have to be given to the circuit structure of the receiving equipment 12 and the signal input stage of the receiving equipment 12 can be supported by the general-purpose unbalanced voltage input circuit having a high input impedance. Therefore, it is not necessary to incorporate any current voltage conversion circuit for exclusive use into the signal input stage of the receiving equipment 12, and an advantage of being able to ensure the general versatility of the signal transmission device is provided.

### Embodiment 2

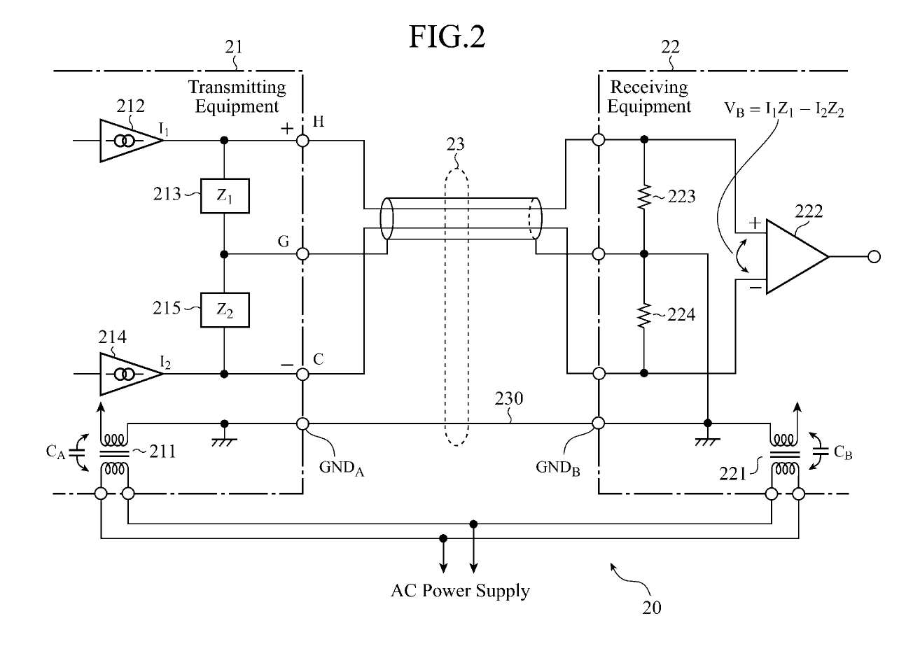

A signal transmission device which uses an unbalanced transmission method is shown as an example of the above-mentioned signal transmission device in accordance with Embodiment 1 of the present invention. Because the common mode rejection ratio can be improved even in a case in which the present invention is applied to a signal transmission device 20 which uses a balanced transmission method which cannot be easily affected by the influence of a noise occurring between transmitting equipment 21 and receiving equipment 22, as shown in FIG. 2, the influence of a noise voltage V_{N} occurring between the grounds (GND_{A}-GND_{B}) of the transmitting equipment 21 and the receiving equipment 22 can be reduced, like in the case of Embodiment 1.

As shown in FIG. 2, in the signal transmission device 20 in accordance with Embodiment 2 of the present invention, the transmitting equipment 21 and the receiving equipment 22 are connected to each other via a transmission path 23 which consists of a three-wire cable having a hot signal line (H), a ground line (G), and a cold signal line (C). In this case, a twisted pair cable can be used as the transmission path 23.

In FIG. 2, the signal output stage of the transmitting equipment 21 is comprised of current output circuits 212 and 214, and load impedances Z₁ (213) and Z₂ (215) for converting currents I1 and I2 created by the current output circuits 212 and 214 into a voltage.

In the signal transmission device 20 which uses the balanced transmission method, the transmitting equipment 21 uses a method of transmitting a signal (−) of opposite phase between the cold and ground lines with respect to a signal (+) transmitted between the hot and ground lines, and it is therefore assumed that the receiving equipment 22 resists being affected by the influence of a noise occurring between the transmitting equipment 21 and the receiving equipment 22 because the receiving equipment removes any extraneous noise between the hot and cold signal lines by using a differential receiver 222, as known well.

The transmission path 23 includes at least a GND signal line 230 which connects between a ground terminal (GND_{A}) of the transmitting equipment 21 and a ground terminal (GND_{B}) of the receiving equipment 22, in addition to the general-purpose three-wire signal line having the hot signal line (+), the cold signal line (−), and the ground line (G).

In FIG. 2, reference numerals 211 and 221 denote power transformers, and reference numerals 223 and 224 denote balanced voltage input circuits having a high input impedance connected to the input stage of the differential receiver 222.

In the above-mentioned structure, even if a difference occurs between the ground potential of the transmitting equipment 21 and that of the receiving equipment 22 (GND_{A} and GND_{B}) and hence a noise voltage V_{N} occurs, the output voltage signal V_{B} which the signal transmission device creates by carrying out current-to-voltage conversion of the output currents I₁ and I₂ of the current output circuits 212 and 214 of the transmitting equipment 21 by using the load impedances Z₁ (213) and Z₂ (215) respectively is created with reference to the ground (GND_{B}) of the receiving equipment 12.

Therefore, because the voltage V_{B} occurring in the receiving equipment 22 becomes equal to V_{B}=I₁Z₁−I₂Z₂ even if the noise voltage V_{N} occurs between the grounds of the transmitting equipment 21 and the receiving equipment 22 (GND_{A} and GND_{B}), the noise voltage V_{N} is not transmitted to the receiving equipment 22 even if the noise voltage V_{N} occurs. Therefore, the influence of the noise voltage can be avoided.

Furthermore, because the load impedances Z₁ (213) and Z₂ (215) are incorporated into the signal output stage of the transmitting equipment 21, the signal input stage of the receiving equipment 22 can be supported by the general-purpose balanced voltage input circuits 223 and 224 having a high input impedance.

In accordance above-mentioned Embodiment 2 of the present invention, the present invention can also be applied to the signal transmission device 20 which employs the balanced transmission method of transmitting a signal of opposite phase between the ground and cold signal lines of the transmitting equipment 21 with respect to a signal between the hot and ground lines, and canceling out a noise between the hot and cold signal lines by using the differential receiver 222 of the receiving equipment 22. Also in this case, the influence of a noise occurring between the grounds of the transmitting equipment 21 and the receiving equipment 22 can be reduced while the general versatility of the signal transmission device is ensured by using the general-purpose balanced voltage input circuits 223 and 224 having a high input impedance in the receiving equipment 22, like in the case of Embodiment 1.

In the above explanation, only the case in which the signal transmission device in accordance with any of Embodiments 1 and 2 of the present invention is applied to audio equipment is shown. The applicability of the present invention is not limited to audio equipment, and the present invention can be applied to any electronic equipment which employs an unbalanced transmission method of using a single signal line for each of many types of analog signals, such as logic signals for use with interfaces, such as an EIA232 serial interface and an IEEE 1284 parallel port interface, TTL, C-MOS, and so on to transmit a signal in the form of a voltage with respect to the ground of the signal.

Furthermore, the present invention can be applied to any electronic equipment including a digital interface for communication equipment or flat-panel display connection, such as a 100 Base-T interface, an ETA485 interface, or an LVDS (Low Voltage Differential Signal) interface, which employs a balanced transmission method of using a pair of two equal signal lines for a single signal line to transmit a signal in the form of a potential difference between the signal lines of the pair.

### INDUSTRIAL APPLICABILITY

Because the signal transmission device in accordance with the present invention can avoid the influence of a noise voltage occurring between the grounds of the transmitting equipment and the receiving equipment without inhibiting the general versatility thereof, and can transmit only a transmission signal to the receiving equipment correctly, the signal transmission device in accordance with the present invention is suitable for use as a signal transmission device in which transmitting equipment and receiving equipment are connected to each other via a transmission path which consists of at least hot and cold signal lines.

1. A signal transmission device in which transmitting equipment and receiving equipment are connected to each other via a transmission path which consists of at least hot and cold signal lines, wherein a signal output stage of the transmitting equipment is comprised of a current output circuit and a load resistance or load impedance for converting a current created by said current output circuit into a voltage, said load resistance or load impedance has an end connected to the hot signal line of said transmission path and another end connected to the cold signal line of said transmission path, and the cold signal line of said transmission path is connected to a ground terminal of said receiving equipment.

2. The signal transmission device according to claim 1, wherein said transmission path includes a grand signal line which connects between a ground terminal of said transmitting equipment and the ground terminal of said receiving equipment.

3. The signal transmission device according to claim 1, wherein said transmitting equipment and said receiving equipment use a single signal line for one signal, and transmit and receive said signal to and from each other in a form of a voltage with respect to a ground of said signal.

4. The signal transmission device according to claim 1, wherein said transmitting equipment and said receiving equipment use a pair of two equal signal lines for one signal, and transmit and receive said signal to and from each other in a form of a potential difference between the signal lines of the pair.
